(19) United States
(12) Patent Application Publication
(10) Pub. No.: US 2018/0206360 A1
(43) Pub. Date: Jul. 19, 2018

(54) HOUSING FOR AN ELECTRICAL DEVICE

(71) Applicant: Stego-Holding GmbH, Schwäbisch Hall (DE)

(72) Inventor: Robert DENT, Schwäbisch Hall (DE)

(21) Appl. No.: 15/743,882

(22) PCT Filed: Jul. 7, 2016
(86) PCT No.: PCT/EP2016/066071

§ 371 Date: Jan. 11, 2018

(30) Foreign Application Priority Data
Jul. 13, 2015 (DE) 10 2015 111 298.1

(51) Int. Cl. H05K 7/20; H05K 7/14; H05K 1/02

(52) U.S. Cl. CPC H05K 7/2039; H05K 7/1427; H05K 2201/066; H05K 7/20127; H05K 1/0201

(57) ABSTRACT

A housing for an electrical device wherein at least a first part of a lower outer wall of the housing is recessed in relation to a second part of the lower outer wall of the housing to form a cooling channel on the lower side of the housing, and wherein a heat sink of the electrical device can be arranged in the housing adjoining the cooling channel such that heat emitted by the heat sink can be dissipated by the cooling channel.

### BACKGROUND

This description relates to a housing for an electrical device.

A variety of housings for electrical devices are known. One problem in previously known housings for electrical devices is that due to the warmth/heat development of the electrical device, an increased temperature can form inside the housing and/or the electrical device, which can result in overheating and therefore damage and/or shutdown of the electrical device. Switching errors and/or malfunctions of the electrical device are also possible in the event of (excessive) heating.

### SUMMARY

This description describes a housing for an electrical device, by means of which overheating of the electrical device can be reliably avoided.

In particular, a housing for an electrical device is described wherein at least a first part of a lower outer wall of the housing is recessed in relation to a second part of the lower outer wall of the housing to form a cooling channel on the lower side of the housing, and wherein a heat sink of the electrical device can be arranged in the housing (directly) adjoining the cooling channel such that heat emitted by the heat sink can be dissipated by means of the cooling channel.

One advantage thereof is that heat emitted by the heat sink is reliably and rapidly dissipated (into the environment). Overheating of the electrical device and/or (strong) heating of the electrical device inside the housing is thus reliably avoided. The temperature of the electrical device inside the housing does not rise (excessively) strongly.

A further advantage is that because of the cooling channel formed, the housing is more stable in relation to forces acting mechanically on the housing. Moreover, the housing is constructed in a technically simple manner and is producible in a technically simple and cost-effective manner.

In one embodiment, the cooling channel is formed open toward the surroundings. In this way, the heat from the heat sink can be dissipated still better from the electrical device in the interior of the housing.

In a further embodiment, the cooling channel essentially has a trapezoidal shape, in particular essentially the shape of an equilateral trapezoid, in cross section perpendicular to the lower outer wall of the housing. One advantage is that the housing is made even more mechanically stable and withstands mechanical forces better. In addition, the heat is dissipated still better in the mentioned form.

The cooling channel can have cooling ribs, in particular extending perpendicularly to the greatest longitudinal extension (longitudinal direction) of the housing. In this way, the heat dissipation performance is increased still further and therefore the heating of the electrical device is reduced still further. Moreover, the mechanical stability of the housing increases further.

In a further embodiment, the housing has first openings in the region of the cooling channel for connecting the cooling channel to the inner side of the housing. One advantage thereof is that the heat can be conducted outward from the heat sink inside the housing and dissipated in a technically simple manner. Moreover, the heat dissipation performance increases in this way. The heat emitted by the heat sink can be transported by means of convection out of the interior of the housing.

The first openings can extend at an acute angle to the greatest longitudinal extension (longitudinal direction) of the cooling channel, in particular at an angle in the range of approximately 35° to approximately 70°, preferably at an angle of approximately 45°, to the greatest longitudinal extension (longitudinal direction) of the cooling channel. A penetration of solid materials (for example, tools) and/or liquid materials (for example, water) through the openings in the housing from outside the housing is thus obstructed and/or prevented. In this way, the electrical device in the housing is better protected from environmental influences, while simultaneously the heat emitted by the heat sink can furthermore be dissipated well. The air resistance is reduced by the corresponding angle.

In a further embodiment, the cooling channel is formed essentially centrally in the lower outer wall of the housing. In this way, the heat can be dissipated particularly well. Moreover, the mechanical stability of the housing increases further. In addition, the heat is dissipated uniformly over the width of the housing.

The cooling channel can extend over essentially the entire length of the housing. The heat can be dissipated particularly well in this way. In addition, the air can flow particularly well through the cooling channel formed and dissipate a large amount of heat in this way. The flow resistance for the air is reduced in this way.

In a further embodiment, at least one side wall, in particular both side walls, of the cooling channel has/have second openings for connecting the cooling channel to the inner side of the housing. One advantage thereof is that the heat of the heat sink can be transported outward and dissipated still better (by means of convection).

The cooling channel can have a width which corresponds to at least approximately one-third of half of the total width of the housing, in particular approximately half of the total width of the housing. The advantage thereof is that the heat can be dissipated still better, since more air can flow through the cooling channel. In addition, the mechanical stability of the housing increases further. In particular, the width of the cooling channel corresponds to at least half of the total width of the lower outer wall of the housing.

In a further embodiment, the housing furthermore comprises the electrical device, wherein the electrical device is arranged in the housing, and wherein the heat sink of the electrical device is arranged in the housing (directly) adjoining the cooling channel such that heat emitted by the heat sink can be dissipated by means of the cooling channel.

One advantage thereof is that heat emitted by the heat sink is dissipated reliably and rapidly (into the surroundings). In this way, overheating of the electrical device and/or (strong) heating of the electrical device inside the housing is reliably avoided. The temperature of the electrical device inside the housing does not rise strongly. A further advantage is that because of the cooling channel formed, the housing is more stable in relation to forces acting mechanically on the housing, so that the electrical device is better protected from mechanical forces. Moreover, the housing is constructed in a technically simple manner and is producible in a technically simple and cost-effective manner.

The electrical device can comprise a printed circuit board, wherein the heat sink is a heat sink of the printed circuit board of the electrical device. Printed circuit boards in particular generate a large quantity of heat in a very small space and/or in a very small volume because of the high concentration/density of components (with ohmic resistances) on the printed circuit board. In addition, electrical and/or electronic parts installed on printed circuit boards are particularly sensitive in relation to an increase of the temperature. Therefore, in a printed circuit board, the dissipation of heat and the prevention of an (excessively) strong temperature increase of components/structural elements on the printed circuit board and/or of the printed circuit board are particularly important. One advantage is that therefore components/structural elements on a printed circuit board and/or a printed circuit board can be reliably cooled, so that no (excessively) strong temperature increases occur of the component/structural elements on a printed circuit board and/or of the printed circuit board inside the housing. In particular, both sides of the printed circuit board, the side facing toward the cooling channel and the side facing away from the cooling channel, are cooled.

The heat sink can be arranged between the printed circuit board and the cooling channel. The heat from the heat sink is emitted particularly well to the cooling channel in this manner and subsequently dissipated thereby.

In a further embodiment, the heat sink comprises wires connected to the printed circuit board, in particular copper wires connected to the printed circuit board, for emitting heat to the cooling channel. It is advantageous therein that the heat sink is designed in a particularly technically simple manner. Moreover, the housing having the heat sink is producible cost-effectively.

The printed circuit board can be arranged in the housing such that both the upper side and also the lower side opposite to the upper side of the printed circuit board can be cooled. Can be cooled means in particular that air can flow along (the upper side and the lower side). Particularly effective cooling of the printed circuit board and/or the components/structural elements on the upper side and the lower side of the printed circuit board is achieved by the two-sided cooling.

### DRAWINGS

The invention will be explained in greater detail hereafter on the basis of drawings of exemplary embodiments. In the figures:

FIG. 1 shows a top view of the front side of a first embodiment of the housing described herein;

FIG. 2 shows a perspective view of the lower side and/or the lower outer wall of the housing 1 from FIG. 1;

FIG. 3 shows a top view of the lower wall of the housing from FIGS. 1 to 2;

FIG. 4 shows a perspective view of the upper side, front side, and a lateral side of the housing from FIGS. 1 to 3;

FIG. 5 shows a perspective top view of the lower outer wall of the housing from FIGS. 1 to 4;

FIG. 6 shows a cross-sectional view perpendicular to the lower outer wall of the housing from FIGS. 1 to 5;

FIG. 7 shows a perspective view of the cross section from FIG. 6;

FIG. 8 shows a top view of a front side of a further embodiment of the housing described herein;

FIG. 9 shows a perspective view of the lower side of the housing from FIG. 8,

FIG. 10 shows a perspective top view of a further, alternative embodiment of the lower outer wall of the housing, and

FIG. 11 shows a perspective view of the lower side of the housing of a further embodiment, in which the lower outer wall of the housing shown in FIG. 10 was used.

### DETAILED DESCRIPTION

In the following description, the same reference signs are used for identical and identically acting parts.

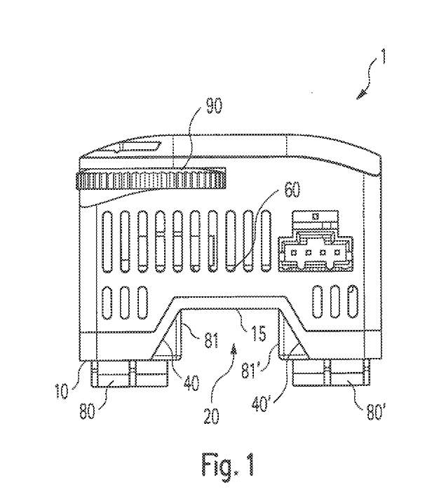

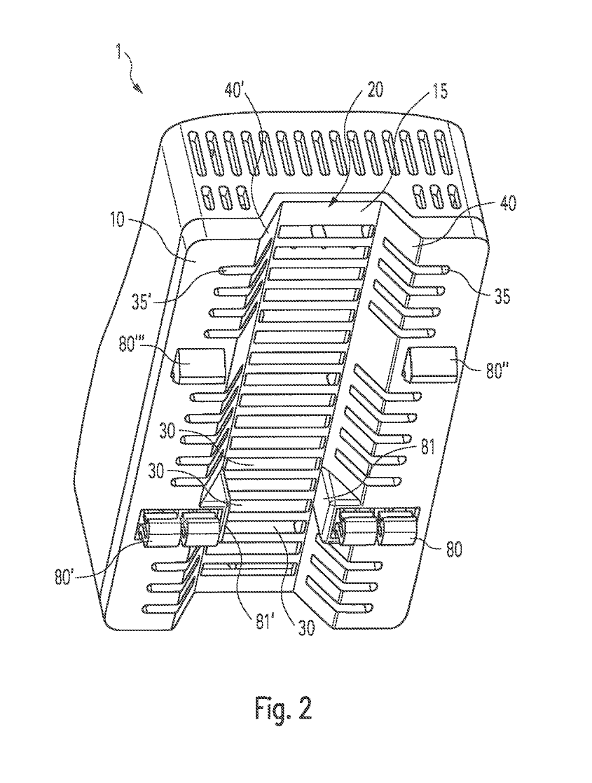

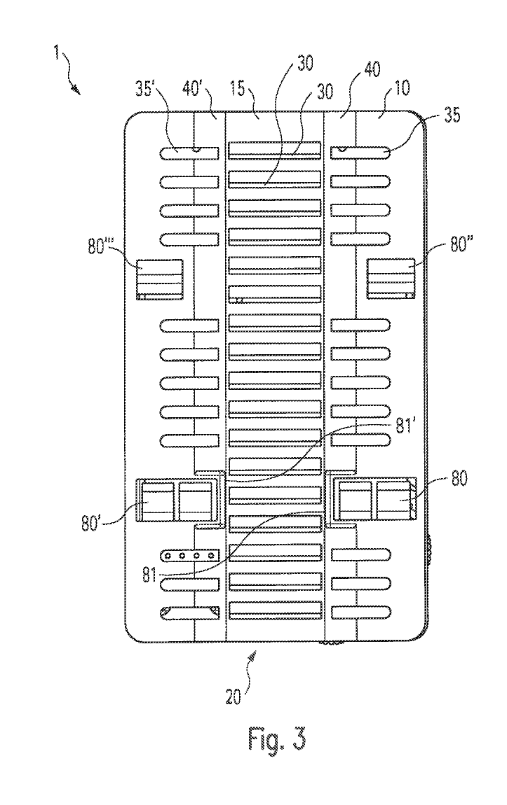

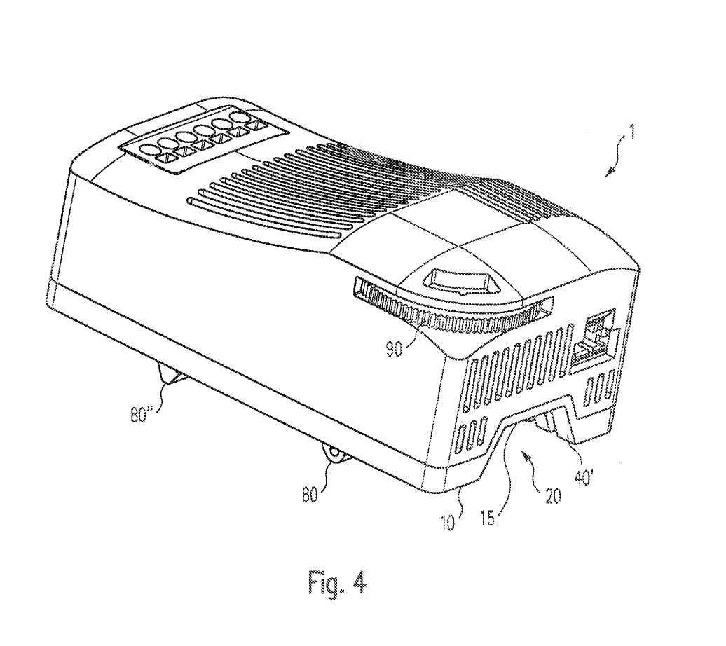

FIG. 1 shows a top view of the front side of a first embodiment of the housing 1. FIG. 2 shows a perspective view of the lower side and/or the lower outer wall of the housing 1 from FIG. 1. FIG. 3 shows a top view of the lower outer wall of the housing 1 from FIGS. 1 to 2. FIG. 4 shows a perspective view of the upper side, front side, and a lateral side of the housing 1 from FIGS. 1 to 3.

The housing 1 has a lower outer wall 10. The term “top” or “lower” relates to an arbitrary outer wall of the housing 1. An (arbitrary) outer wall of the housing 1 is merely to be unambiguously identified by the term “lower”. The terms “lower” and “upper” refer hereafter to the alignment of the housing in FIG. 1.

A first part 15 of the lower outer wall of the housing 1 is recessed in relation to the remaining second part of the lower outer wall 10. Due to the recess of a part 15 of the lower outer wall 10 of the housing 1, an essentially trapezoidal cooling channel 20, formed in particular in the form of an equilateral trapezoid, is formed. The cooling channel 20 formed has two side walls 40, 40′ extending diagonally in relation to the non-recessed second part of the lower outer wall 10 and in relation to the recessed first part 15 of the lower outer wall of the housing 1. The side walls 40, 40′ connect the recessed first part 15 of the lower outer wall of the housing 1 to the non-recessed second part of the lower outer wall 10 of the housing 1.

The recessed first part 15 of the lower outer wall of the housing 1 extends in parallel to the second non-recessed part 10 of the lower outer wall of the housing 1. However, it is also conceivable that the cooling channel 20 has another shape, for example, square, rectangular, having curved faces, etc. It is also conceivable that the recessed first part 15 of the lower outer wall of the housing 1 does not extend parallel to the non-recessed part 10 of the lower outer wall of the housing 1.

It can be seen clearly in FIG. 1 that projections 81, 81′ of fastening hooks 80, 80′, 80″, 80′″, project into the cooling channel 20. When indicating the shape of the cooling channel 20 (for example, trapezoidal, shape of an equilateral trapezoid, etc.), these projections 81, 81′ were left out of consideration.

Instead of a trapezoidal cooling channel 20, the cooling channel can alternatively be formed in the shape of a circular arc, an ellipsoid arc, or rectangular.

The cooling channel 20 is open to the outside (i.e., to the surroundings). This means that two parts of the non-recessed lower outer wall 10 of the housing which are separated from one another by the cooling channel 20 are not connected to one another by a further wall, inter alia. This can be seen clearly in FIG. 1. No further element of the housing 1 is located below the recessed first part 15 of the lower outer wall of the housing 1. However, it is also conceivable that at the lower end of the side walls 40, 40′ of the cooling channel 20, a type of wall connects the two outer second non-recessed parts 10 of the lower outer wall of the housing 1. The cooling channel 20 was therefore formed by four walls, namely the recessed part 15 of the lower outer wall, the two side walls 40, 40′, and a connecting wall. However, this embodiment is not shown in the figures.

The two side walls 40, 40′ each have an angle for influencing the convection in relation to the second non-recessed part 10 of the lower outer wall and the first recessed part 15 of the lower outer wall of the housing 1. In particular, the angle can have a value from the range of approximately 35° to approximately 70°, preferably a value from the range of approximately 40° to approximately 65°, for example, approximately 45°. Angles such as, for example, approximately 60°, approximately 30° approximately 35° or approximately 40° and also approximately 50° are also conceivable.

The cooling channel 20 is used to dissipate heat emitted by a heat sink of an electrical device and/or a printed circuit board 60 inside the housing 1. Air can flow through the cooling channel 20 and therefore dissipate heat from the heat sink. This has the result that the temperature of the heat sink sinks and therefore the temperature of the electrical device and/or the printed circuit board 60 of the electrical device sinks. In this way, the temperature sinks inside the housing 1.

The cooling channel 20 extends over the entire length (greatest longitudinal extension) of the housing 1 in the embodiments shown in the figures. This longitudinal direction extends from bottom to top or from top to bottom in FIG. 3. The total width of the outer wall 10 of the housing 1 is the maximum extension of the housing 1 in FIG. 3 from left to right, i.e., the width direction extends from left to right in FIG. 3 and also from left to right in FIG. 1.

However, of course, it is also conceivable that the cooling channel does not extend over the entire length, but rather over only a part of the length of the housing 1.

First openings 30 are formed in the recessed part 15 of the lower outer wall of the housing 1. These first openings 30 form a connection between the interior of the housing 1 and the cooling channel 20. Air can flow through the first openings 30. The air transports heat from the heat sink inside the housing 1 outward by means of convection (into the cooling channel) and dissipates it.

In a simple embodiment, the first openings 30 simply consist of a gap (extending perpendicularly to the flow channel 20). In the embodiments shown in the figures, the openings have an angle of approximately 45° in relation to the plane which extends along the first recessed part 15 of the lower outer wall of the housing and/or along the second non-recessed part of the lower outer wall 10 of the housing. This means that the first openings 30 have diagonally extending walls in relation to the cooling channel 20.

These walls of the first openings 30 are clearly visible in FIG. 3. In the top view from below (shown in FIG. 3) they each extend over approximately ¾ of the width of the respective gap in the first recessed part 15 of the lower outer wall and/or lower side of the housing 1. This means that only approximately ¼ of the width of the first openings 30 perpendicular to the recessed part 15 of the lower outer wall of the housing 1 leads directly into the housing 1. Via the remaining region of the gaps in the first recessed part 15 of the lower outer wall, if one attempted, for example, using a screwdriver to reach the interior of the housing perpendicularly to the recessed part 15 of the lower outer wall of the housing 1, one would strike at or on the wall of the openings 30, which extends at an angle of approximately 45° to the lower outer wall of the housing. This prevents or obstructs a direct contact from being able to be established with current-conducting elements inside the housing 1, which prevents electric shocks. A touch protection is achieved. In particular, the protection class IP20 according to DIN 40 050-9:1993-05/DIN EN 60529 is thus achieved. This means that the elements in the housing 1 are protected against solid foreign bodies having diameter from 12.5 mm and against access with a finger.

In the event of a touch of the cooling channel 20, for example, with a hand and/or a finger, the hand is therefore prevented from touching current-conducting elements inside the housing. This increases the level of safety for the user. Moreover, when one touches the recessed part 15 of the lower outer wall with the hand, for example, sensitive electronic structural elements of the electronic device and/or printed circuit board 60 are prevented from coming into contact with the hand and/or fingers. Sensitive electronic structural elements of the electrical device and/or circuit board 60 are therefore protected from static electricity/electrostatic charge of humans in this way, which could destroy or damage the structural elements. In this way, corresponding safety standards, in particular with respect to the touch safety, can be fulfilled in a technically simple manner.

Instead of the first openings 30, it is also conceivable that the cooling channel does not have any first openings. The cooling channel 20 could have a planar surface as the upper wall and/or recessed part 15 of the lower outer wall of the housing 1.

Alternatively, the cooling channel 20 could have cooling ribs, which extend downward (in FIG. 1) from the recessed part 15 of the lower outer wall of the housing 1. The surface area of the cooling channel 20 is increased by these cooling ribs.

A combination of first openings 30 and cooling ribs is also conceivable. For example, first openings 30 and cooling ribs could alternatively alternate along the cooling channel 20 in the longitudinal direction of the cooling channel 20 and/or the housing.

Multiple fastening hooks 80, 80′, 80″, 80′″ are arranged on the lower outer wall 10 of the housing 1, by means of which the housing 1 can be fastened on a top-hat rail, for example. Because of the extension of the lower fastening hooks 80, 80′ in FIG. 2, a projection 81, 81′ respectively protrudes into the cooling channel 20. However, it is also conceivable that no projections 81, 81′ protrude into the cooling channel 20.

The side walls 40, 40′ have second openings 35, 35′, which form a connection between the surroundings and/or the cooling channel 20 and the interior of the housing 1. The second openings 35, 35′ each extend over approximately ⅘ of the width of the side walls 40, 40′. In FIG. 1, the width of the side walls extends from bottom left to top right or from bottom right to top left, respectively. The second openings 35, 35′ also extend over a smaller part of the second non-recessed part of the lower outer wall 10 of the housing 1.

The (width of the) first openings 30, 30′ extend perpendicularly to the longitudinal direction of the housing 1 (in FIG. 3, the longitudinal direction of the housing 1 and the cooling channel 20 extends from top to bottom). The second openings 35, 35′ also extend perpendicularly to the longitudinal direction of the housing 1 and therefore perpendicularly to the cooling channel 20.

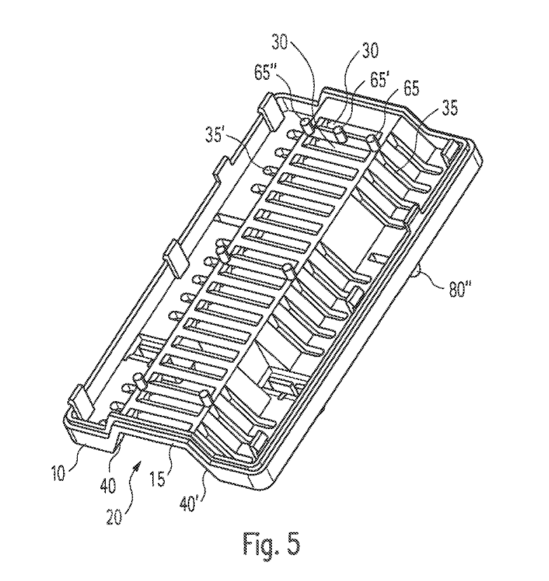

FIG. 5 shows a perspective top view of the lower outer wall of the housing 1 from FIGS. 1 to 4. FIG. 5 shows the lower outer wall 10 of the housing 1 and the recessed part 15 of the lower outer wall of the housing 1. Multiple spacers 65, 65′, 65″ are arranged along the cooling channel 20 inside the housing 1. They are used to define the spacing between the electrical device and/or the printed circuit board 60 and the recessed part 15 of the lower outer wall of the housing 1. In this way, the printed circuit board 60 can be arranged and/or fastened at a defined position inside the housing 1. This defined position can also be maintained by the spacers 65, 65′, 65″ if parts of the components/structural elements on the printed circuit board 65 protrude beyond the lower side of the printed circuit board 65 (for example, IC pins). Due to the defined spacing of the printed circuit board 65 from the recessed part 15 of the lower outer wall of the housing 1, an electrical safeguard is additionally also achieved, since no part of the human body can come closer than this predetermined spacing (plus the thickness of the recessed part 15 of the lower outer wall of the housing 1) to the printed circuit board 65 and/or the components on the printed circuit board 65.

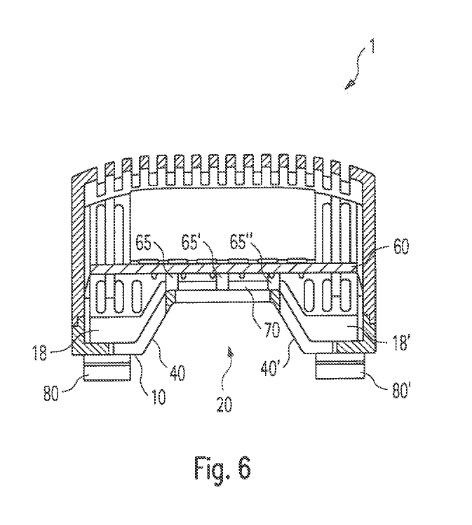

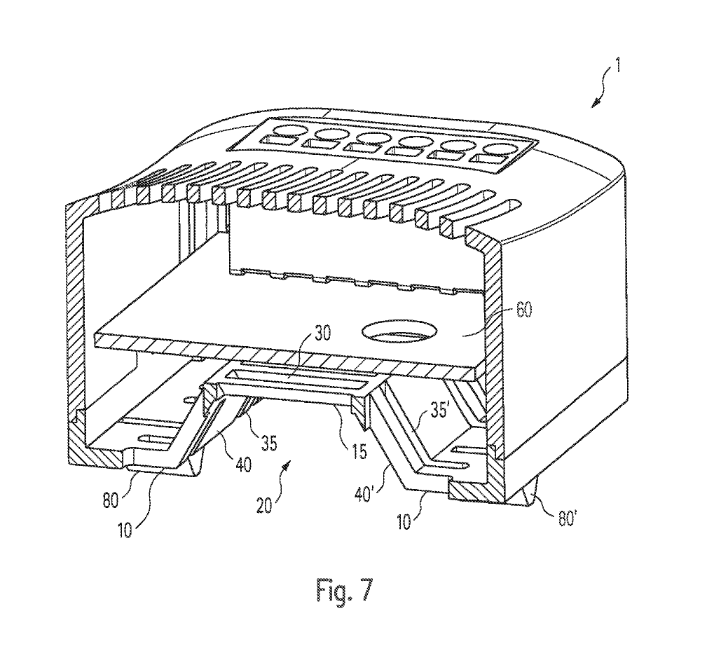

FIG. 6 shows a cross section perpendicular to the longitudinal direction of the housing 1 and perpendicular to the lower outer wall 10, 15 of the housing 1. FIG. 7 shows a perspective view of the same cross section which is shown in FIG. 6. A printed circuit board 60 is arranged inside the housing 1. It is held by the spacers 65, 65′, 65″ at a defined spacing from the recessed part 15 of the lower outer wall of the housing 1. The printed circuit board 60 generates heat during operation of the electrical device, of which it is a part. This heat has to be dissipated, to prevent an increase of the temperature of the printed circuit board 60 and/or inside the housing 1. The heat sink is used for this purpose. It dissipates heat from the printed circuit board 60 and emits it to the air.

In particular, a heat sink 70 is located on the side of the printed circuit board 60 facing toward the lower outer wall of the housing 10. The heat on the printed circuit board is discharged by targeted measures into the heat sink. The heat is emitted to the air on the lower side of the printed circuit board 60 and/or a part of the lower side of the printed circuit board 60. The or most of the structural elements of the printed circuit board 60 are arranged on the upper side of the printed circuit board 60. The heat sink 70 therefore comprises the entire region and/or the largest part of the region which is located between the lower side of the printed circuit board 60 and the cooling channel 20. In particular, both sides of the printed circuit board 60, the (lower) side facing toward the cooling channel and the (upper) side facing away from the cooling channel are cooled.

Alternatively, the heat sink 70 can comprise and/or consist, for example, of metal wires protruding from the printed circuit board 60 in the direction of cooling channel 20, in particular protruding copper wires which dissipate heat from the printed circuit board 60 and/or emit it to the air.

In the heat sink, heat is emitted to the air, which is located in the immediate surroundings. I.e., heat is emitted to air which is located between the lower side of the printed circuit board 60 and the cooling channel 20. This heated air can flow through the first openings 30 out of the housing. Turbulence, by which laminar layers are broken up, forms due to the formation of the cooling channel 20 and natural convection. In this way, an increase or excessively strong increase of the temperature inside the housing and in particular of the components on the printed circuit board 60 or of the printed circuit board 60 is prevented. Damage to components/parts of the printed circuit board, which can result in malfunctions, is thus substantially prevented or at least reduced. Temporary functional disturbances are also prevented or at least reduced in this way.

The heat sink 70 can extend along the entire cooling channel 20. Alternatively, the heat sink can only be located at specific regions of the cooling channel 20 (only parts of the total width of the cooling channel or parts of the total length of the cooling channel).

It is also conceivable that the heat sink is arranged on the side of the printed circuit board 60 facing away from the cooling channel 20.

The cooling channel 20 has a width which extends perpendicularly to the longitudinal direction of the housing 1 (the width extends from left to right in FIG. 3), which corresponds to approximately ⅔ of the total width of the housing 1 and/or the lower outer wall 10 of the housing 1.

The mechanical stability of the housing is increased by the recessed part 15 of the outer wall of the housing 1 and the cooling channel 20 thus formed. In particular forces occurring laterally (from the left and/or from the right in FIG. 6) on the housing 1 can be distributed better onto the housing 1. The housing 1 is therefore made more mechanically stable.

The housing 1 also has openings on its upper side (opposite to the lower outer wall 10 of the housing 1), to dissipate air and heat. Further openings, which dissipate air and heat, are also located on the front side.

Two cavities 18, 18′ are formed between the printed circuit board 60 and the (two-part) non-recessed part 10. The air circulation and heat dissipation from the printed circuit board 60 are improved by these cavities 18, 18′. Moreover, additional heat, which only occurs at certain points in time and exceeds the typical heat generation, is absorbed in the cavities 18, 18′. The emission of radiant heat by the components of the printed circuit board 60 and/or by the printed circuit board 65 and the convection is promoted in this way. The cavities 18, 18′ can form a part of the heat sink.

The heat dissipation and/or heat removal can be improved still further by the movement of the air being increased by a fan, for example.

In FIG. 1, the housing 1 comprises a gap in which an adjustment wheel 90 is arranged. By means of the adjustment wheel 90, which is rotatably mounted in the gap, a value to be input can be transferred and/or set or on the electrical device inside the housing. For example, a specific temperature to be regulated, which is to be regulated by means of the electrical device, can be set by means of the adjustment wheel 90. This temperature to be regulated is not the temperature occurring inside the housing 1, however, as a result of the heat development of the electrical device.

The upper side of the housing 1 has a concave surface in the vicinity of the adjustment wheel 90. This concave surface merges into a convex surface in FIG. 4 from the front right to the rear left. The two side walls of the housing 1 and also the rear wall (opposite side of the front side shown in FIG. 1) are perpendicular to the lower outer wall 10 of the housing 1.

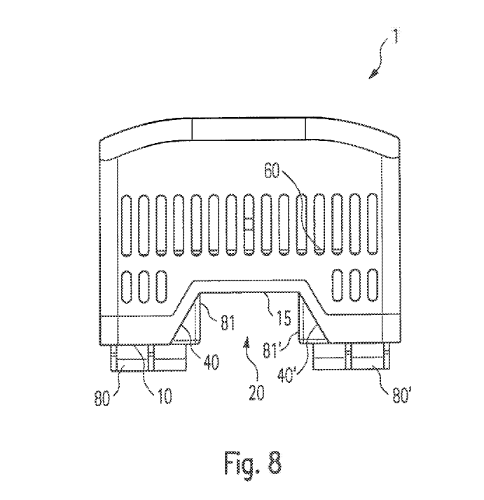

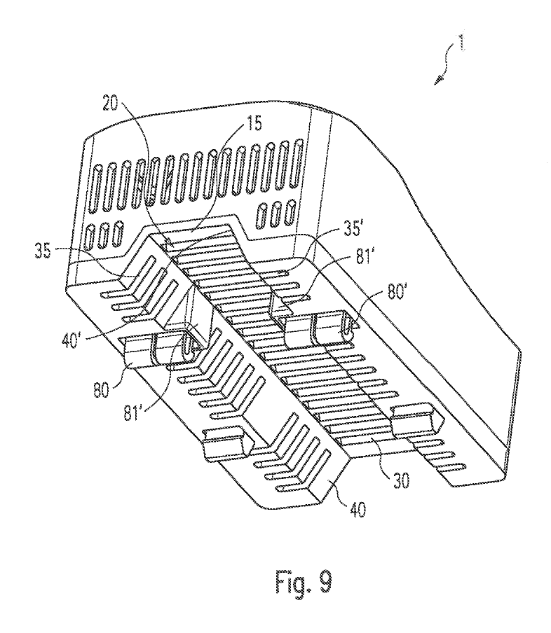

FIG. 8 shows a front top view of a further embodiment of the housing 1. FIG. 9 shows a perspective view of the lower side of the housing 1 from FIG. 8. The housing 1 in FIG. 8 and/or FIG. 9 differs from the housing 1 shown in FIGS. 1 to 7 solely in that no adjustment wheel 90 and accordingly no gap provided for this purpose is present.

The electrical device in the housing can be and/or comprise, for example, a switching module, an electrical switching device, a heating temperature control unit.

In particular, the electrical device can be and/or comprise an electronic thermostat. The electrical device and/or the electronic thermostat can be used in particular for controlling heating and cooling devices, filter fans, or signal encoders. The electronic thermostat detects the ambient temperature and can switch ohmic and inductive loads. The thermostat measures the ambient temperature by means of an internal or external thermal sensor, which is advantageously uninfluenced by the temperature in the interior of the housing 1, and regulates an external heating and/or cooling device or a heater on the basis of the measured value. In particular, the desired temperature can be set using the adjustment wheel 90. The adjustment wheel 90 can latch at specific positions.

The electrical device in the housing 1 can control and/or regulate external electrical and/or electronic devices

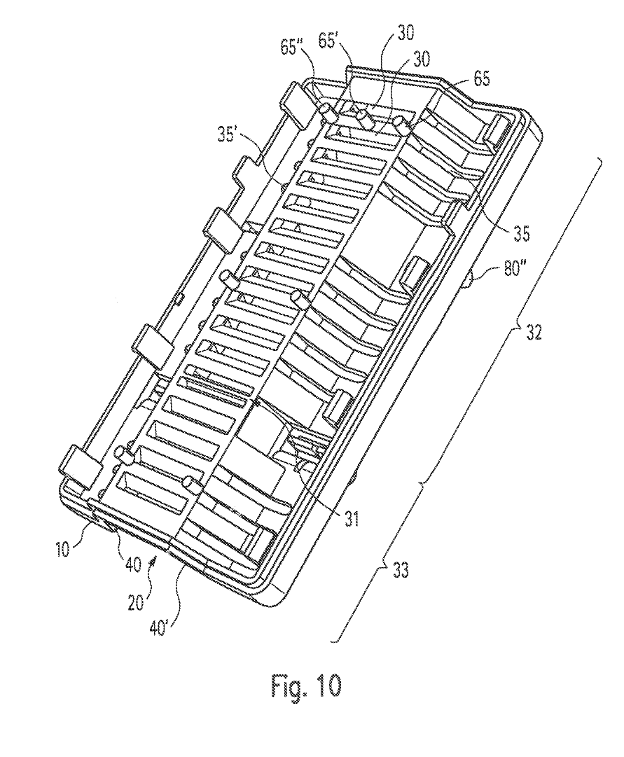

FIG. 10 furthermore shows a perspective top view of a further alternative embodiment of the lower outer wall of the housing 1. The embodiment shown in FIG. 1 differs from the embodiment shown in FIG. 5 solely in that in FIG. 5, the first openings 30 extend in the same direction (toward the top right), while in FIG. 10, a part of the first openings 30 (the 11 first openings in the upper region 32 of the recessed part 15 of the lower outer wall in FIG. 10) extend in the same direction (namely to the top right) and a part of the first openings (the 4 first openings in the lower region 33 of the recessed part 15 of the lower outer wall in FIG. 10) extend to the bottom left. The profile shape and/or direction of the first opening is described in each case along the imaginary movement direction from the interior of the housing 1 to the exterior of the housing 1. A type of first double opening is shown between the upper region 32 of the first openings 30 and the lower region 33 of the first openings 30, which has two smaller first openings, namely one corresponding to the upper region 32 of the first openings 30 (open to the top right) and one corresponding to the lower region of the first openings 30 (open to the bottom left). This double opening 31 represents the transition between the two regions 32, 33 of the first openings 30.

The air circulation and/or heat dissipation can be further improved by the differing alignment and/or opening direction of the first openings 30. The arrangement of the first openings 30 with the one opening alignment or the other opening alignment is adapted to the position of the warmest/hottest point of the printed circuit board 60 and/or the warmest/hottest point inside the heat sink.

The position of the double opening 31 and therefore the extension of the upper region 32 and the lower region 33 can be adapted accordingly during the production of the housing.

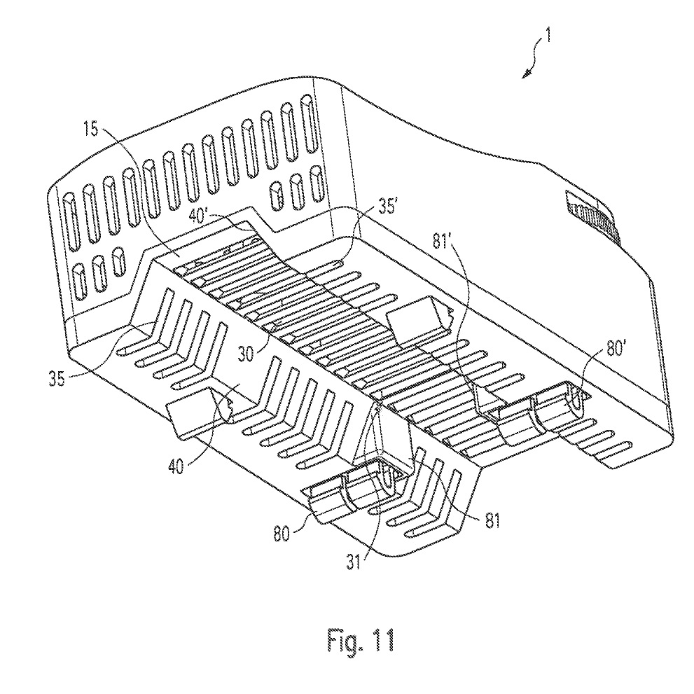

FIG. 11 shows a perspective view of the lower side of the housing 1 of a further embodiment, in which the lower outer wall of the housing 1 shown in FIG. 10 was used. The position of the rotating wheel is mirrored in relation to the embodiment(s) shown in FIGS. 1-8.

1. A housing for an electrical device,
wherein at least a first part of a lower outer wall of the housing is recessed in relation to a second part of the lower outer wall of the housing to form a cooling channel on the lower side of the housing,
and wherein a heat sink of the electrical device can be arranged in the housing adjoining the cooling channel such that heat emitted by the heat sink can be dissipated by means of the cooling channel.

2. The housing according to claim 1, wherein the cooling channel is formed open toward the surroundings.

3. The housing according to claim 1, wherein the cooling channel essentially has a trapezoidal shape, in particular essentially the shape of an equilateral trapezoid, in cross section perpendicular to the lower outer wall of the housing.

4. The housing according to claim 1, wherein the cooling channel has cooling ribs, in particular extending perpendicularly to the greatest longitudinal extension (longitudinal direction) of the housing.

5. The housing according to claim 1, wherein the housing has first openings in the region of the cooling channel for connecting the cooling channel to the inner side of the housing.

6. The housing according to claim 5, wherein the first openings extend at an acute angle to the greatest longitudinal extension (longitudinal direction) of the cooling channel, in particular at an angle in the range of approximately 35° to approximately 70°, preferably at an angle of 45°, to the greatest longitudinal extension (longitudinal direction) of the cooling channel.

7. The housing according to claim 1, wherein the cooling channel is formed essentially centrally in the lower outer wall of the housing.

8. The housing according to claim 1, wherein the cooling channel extends over essentially the entire length of the housing.

9. The housing according to claim 1, wherein at least one side wall, in particular both side walls of the cooling channel has second openings for connecting the cooling channel to the inner side of the housing.

10. The housing according to claim 1, wherein the cooling channel has a width which corresponds to at least approximately one-third of the total width of the housing, in particular approximately half of the total width of the housing.

11. The housing according to claim 1, furthermore comprising the electrical device,
wherein the electrical device is arranged in the housing,
and wherein the heat sink of the electrical device is arranged in the housing adjoining the cooling channel such that heat emitted by the heat sink can be dissipated by means of the cooling channel.

12. The housing according to claim 11, wherein
the electrical device comprises a printed circuit board,
and wherein the heat sink is a heat sink of the printed circuit board of the electrical device.

13. The housing according to claim 12, wherein
the heat sink is arranged between the printed circuit board and the cooling channel.

14. The housing according to claim 13, wherein the heat sink comprises wires connected to the printed circuit board, in particular copper wires connected to the printed circuit board, for emitting heat to the cooling channel.

15. The housing according to claim 12, wherein the printed circuit board is arranged in the housing such that both the upper side and also the lower side opposite to the upper side of the printed circuit board can be cooled.
